(19) United States
(12) Patent Application Publication
(10) Pub. No.: US 2007/0015383 A1
(43) Pub. Date: Jan. 18, 2007

(54) Plug-in connector

(76) Inventors: Michael Jahn, Hoyerswerda (DE); Georg Kaufl, Maierhofen (DE)

Correspondence Address: CONTINENTAL TEVES, INC., ONE CONTINENTAL DRIVE, AUBURN HILLLS, MI, 48326-1581, US

(21) Appl. No.: 10/546,181

(22) PCT Filed: Nov. 11, 2003
(86) PCT No.: PCT/DE03/03686

§ 371 Date: Jun. 21, 2006

(30) Foreign Application Priority Data
Feb. 21, 2003 (DE) 10307663.8

(51) Int. Cl. H05K 1/00

(52) U.S. Cl. 439/76.2

(57) ABSTRACT

The present device relates to a plug-in connector including a plug and a socket with a housing for connecting conduits to a consumer device, such as an electronic regulator or an electronic controller of an automobile. To achieve a compact construction and reduced space requirements, several individual plugs are interconnected to form a plug group and the socket is configured in such a way that the individual plugs that are inserted into the plug housing form a modular plug group comprising at least two individual plugs arranged in a row. Thus, intermediate walls between individual plugs can become superfluous and a specific insertion and removal sequence of individual plugs can be defined.

### BACKGROUND OF THE INVENTION

The invention relates to a plug-in connector comprising a plug and a socket with a housing for connecting conduits to a consumer device, preferably to an electronic regulator or electronic controller of an automobile, the contacts of the plug being brought into contact with the connection contacts of the socket.

The invention relates to a plug-in connector substantially comprising a plug and a socket for connecting a cable, which can contain at least a plurality of signal conduits and if necessary also power supply conduits to a consumer device, the contacts of the plug being in contact with the connection contacts of the socket.

Plug-in connectors are known for example from EP-A 592212 and JP-A-9102362. If e.g. the plug-in connector is a component of the door control device of an automobile, which is to be accommodated in the door of the automobile, it is absolutely necessary to adapt the plug-in connector and thus the control device to the required space of the door interior and thus to construct the plug-in connector to require less space according to the narrow space proportions prevailing in the door interior. The plug of the plug-in connector and the plug housing or lower shield of the plug is to be configured in terms of the number of the required contacts such that they can be easily adapted to the different equipment versions, such as electrically adjustable and/or heated outside mirrors, central locking systems, lighting versions and the like of an automobile, that they are cost-effective and nevertheless with the high loads exposed to in an automobile ensure a maintenance-free connection during service life of the automobile.

### SUMMARY OF THE INVENTION

It is, therefore, the object of the invention to design a plug-in connector of this type such that with a relatively simple, however compact construction and high mechanical load and resistivity it requires low space and shows a high flexibility inherent to scalable individual plug-in connectors with continuous stress while maintaining the compact construction of large multipolar plug-in connectors. Furthermore, it should be an easily lockable and releasable plug-in connector, to minimize assembly expenditure during manufacturing of the automobile and its maintenance.

It has been shown that this object can be achieved by a plug-in connected having a socket that is configured so that when inserting individual plugs into the plug housing a modular plug group with at least two individual plugs arranged in a row is formed.

It is particularly advantageous to use the plug-in connector consisting of plug and plug housing in a door control device of an automobile.

Further advantageous embodiments of the invention are are described herein.

For achieving a compact space-saving construction of a large multipolar connection, the plug-in connector is advantageously configured such that the individual plugs each comprise a connection unit, which connects the one individual plug to the back of the other individual plug. It is advantageous that the connection is friction-locked or form-fit. Here, the connection unit comprises a locking mechanism, which engages when inserting individual plugs into the plug housing via an elastic element with a detent into the back of the respective other individual plug.

For an easy disassembly of the plug group it is advantageously provided that the connection unit comprises an unlocking device, which removes the detent from the back of the respective other individual plug when withdrawing the elastic element.

For preguiding the plug and thus “finding” of the contacts it is advantageously provided that each individual plug comprises a guiding and coding web, which is brought into contact with a component profiled accordingly and which combines the components when inserting individual plug and plug housing. An assembly protection against an individual plug distorted by 180 degrees is ensured by coding, as the web is arranged eccentrically and if necessary one-sided at the individual plug related to its center.

The position of the contacts is irrespective of the number of contact types used and permits high flexibility of the used printed circuit boards in the door control device. Adaptation of the footprints on the printed circuit board to the currently used customized plug systems with different detent/row distances can be easily standardized.

The individual plugs can advantageously be combined to a compact multipolar plug group for connecting conduits to a consumer, wherein it is advantageously provided that the plug group is composed of modular individual plugs such that at least two individual plugs, which are arranged one after the other in a row, form a plug group. In this context each individual plug advantageously comprises a guiding and coding web.

Individual plugs are configured advantageously such that they comprise a connection unit with a locking and unlocking unit, which comprises an elastic element with a detent and wherein the elastic element is fixed to a side of the individual plug which faces the contacts and is free to be moved at the side of the individual plug which is opposite to the contacts.

Reduction of space requirements is advantageously achieved in that the plug housing does not comprise any intermediate walls in the connecting region of the individual plugs. Advantageously, sockets for guiding and coding webs are provided in the plug housing, which guide joining of the components when plugging individual plug and socket.

### BRIEF DESCRIPTION OF THE DRAWINGS

An example of an embodiment is shown in the drawings and is explained in detail in the following.

FIG. 1 shows a simplified perspective view of a plug connection with plug housing and inserted individual plugs

FIG. 2 shows a section through a plug housing with the individual plugs

FIG. 2a shows a detailed view of an appropriate individual plug

FIG. 3 shows a top view of a door control with inserted plugs

FIG. 4 shows a top view of a door control with plug housing

FIG. 5 shows a perspective top view of a section through the plug housing with individual plugs, which comprise lateral locking mechanisms

FIG. 6 shows a functional diagram for the arrangement according to FIG. 5

FIG. 7 shows an explosion draft for a detailed view of an embodiment according to FIG. 5

### DETAILED DESCRIPTION OF THE DRAWINGS

The examples of embodiments of the plug-in connector according to the invention shown hereinafter in the drawings will be used in particular in applications with problems regarding construction space, e.g. for an electronic control of an automobile, such as the door control device, and the units to be controlled, such as central locking system, outside mirror, lighting and the like, electrically connected. A plug-in connector of this type is to be configured with particularly low space requirements and in compact manner, if the electronic control is located in the door of the vehicle.

Like reference numerals refer to like elements, like reference numerals with different indices referring to like elements at the respective individual plugs.

The size of the plug depends on the system and can be flexibly adapted to the requirements of an automobile, for example can be configured as 26 polar and 47 polar plug-in connector with 2 to 10 polar individual plugs. It goes without saying that the construction according to the invention is also suitable for other sizes.

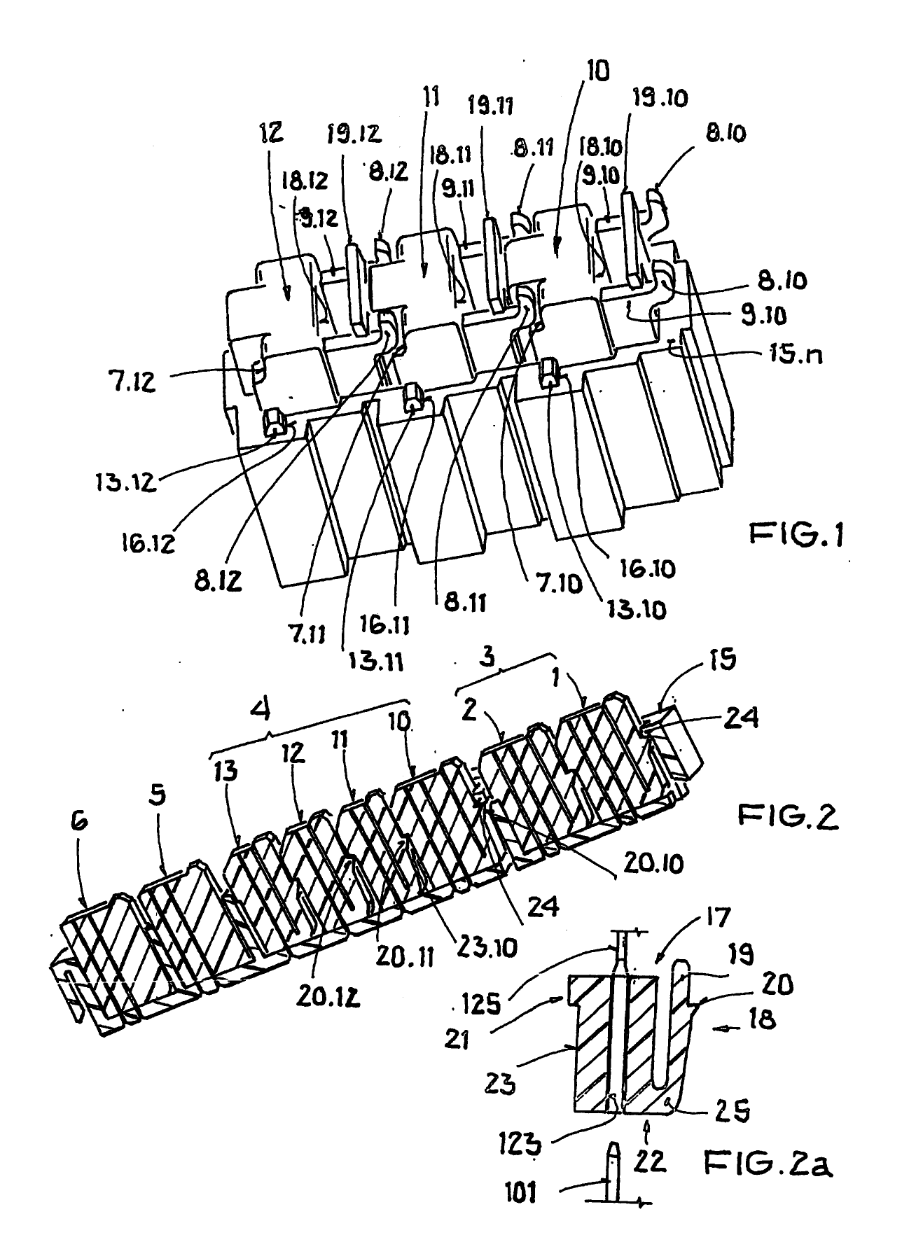

FIG. 1 shows a first example of embodiment of a modular plug composed of several individual plugs 10, 11, 12 inserted into the plug housing 15.

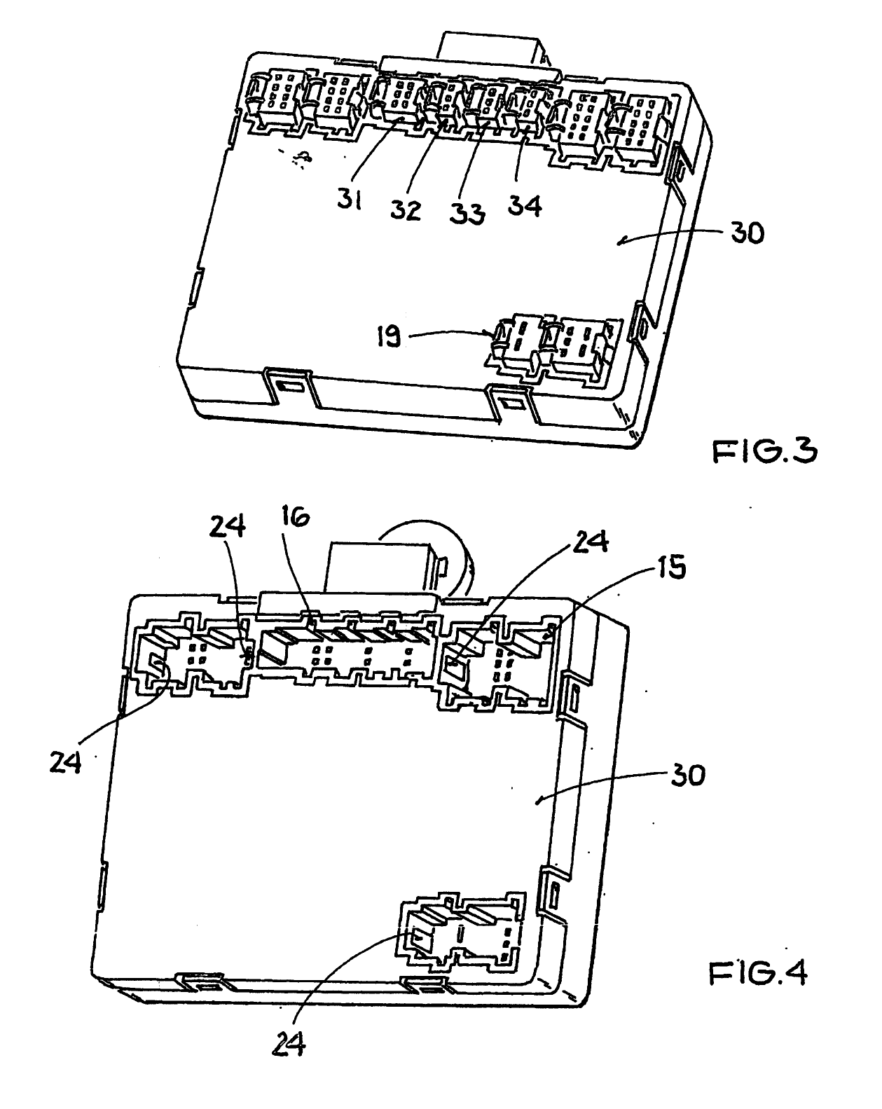

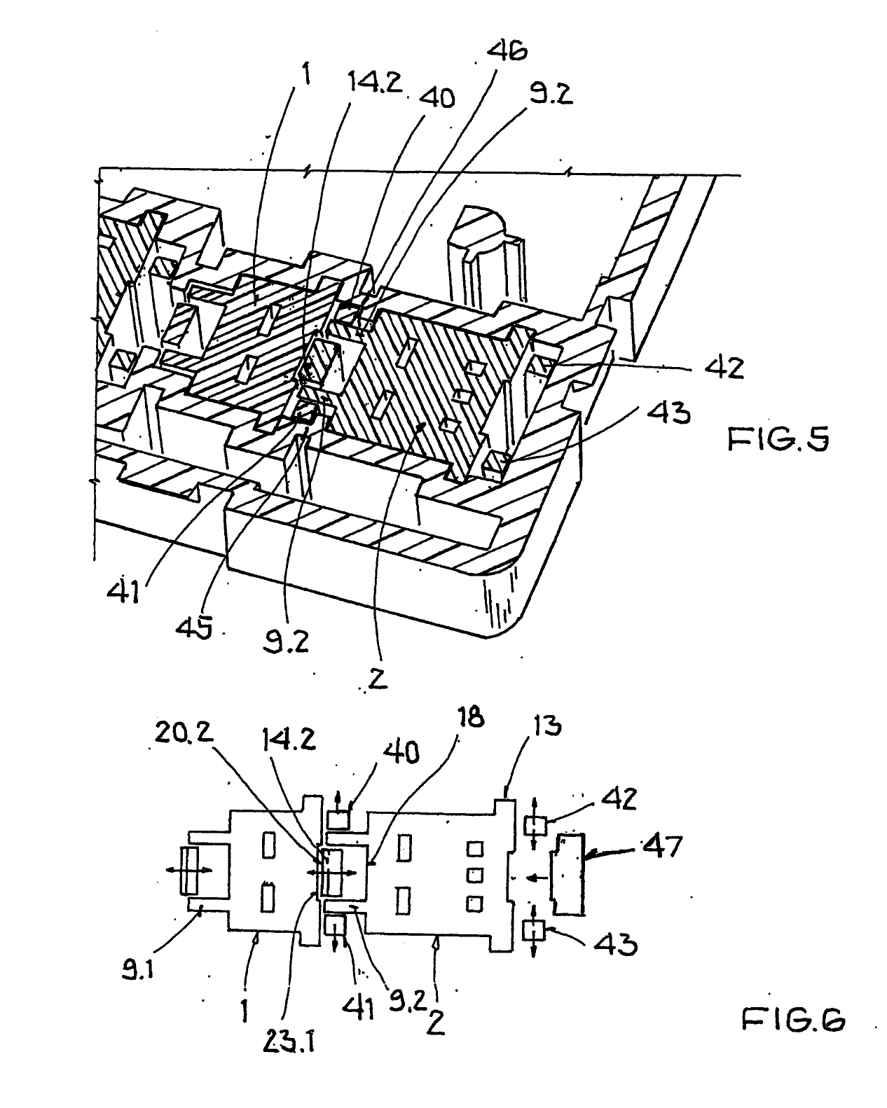

The shown plug housing or plug shroud 15 is part of a socket. The plug shroud 15 is located on or—as is shown in FIGS. 3 and 4—in a control housing 30 and can be jointly manufactured with it, e.g. by injection-molding; use of a pre-injection molding or of a prefabricated insert is also possible.

In the shown example of embodiment transversely directed guideways 16 are located in the plug housing, which guideways together with the guiding and coding webs 13 of the plugs 10, 11, 12 assume the following functions:

Preguiding of the Individual Plugs 10, 11 or 12:

By means of the height of the guideways 16, 16.1, 16.2 it is ensured that during assembly of the individual plugs 10, 11, 12 at first the guiding webs 13, 13.1, 13.2 of each individual plug emerge into the guideways. This enables a more accurate preguiding; finding of the contacts of the plug-in connector—plug and socket—is facilitated. There is a shorter “tolerance chain” than with corresponding plugs without such guide webs.

Coding:

By arranging eccentrically arranged guiding webs they also assume a coding function. An assembly protection against an individual plug 10, 11, 12 distorted by 180 degrees is ensured,. An assembly protection against an individual plug 10, 11, 12 distorted by 180 degrees is ensured, as the webs 13 are arranged eccentrically related to the longitudinal direction of the individual plugs 10, 11, 12

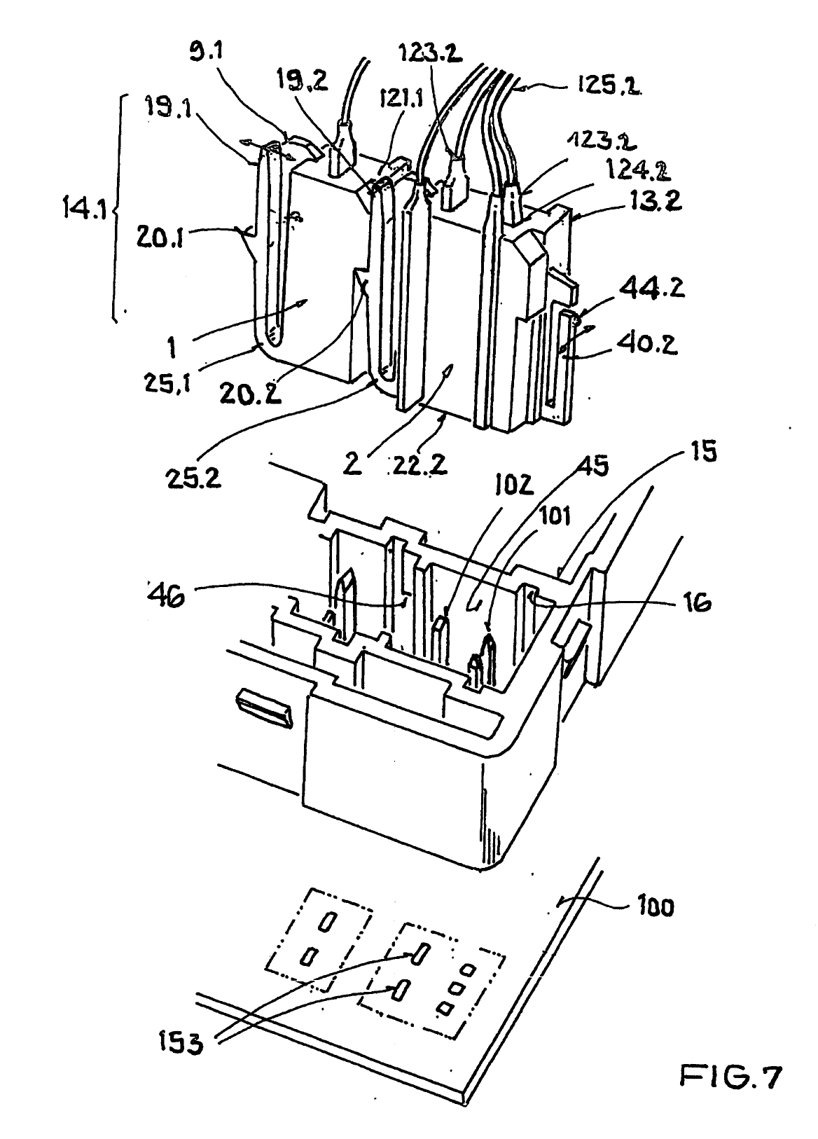

The individual plugs 10, 11, 12 are arranged essentially form-fit in the plug housing 15 and comprise an elastic substantially plane operational control 14, which at the side 17 opposite to the contacts (cp. No. 101 in FIGS. 2 and 7) sticks out of the front 18 of the individual plugs and at the side 22 facing the contacts is connected to the front of the individual plugs 10, 11, 12. The elastic operational control 14, 14.1, 14.2 comprises an operating surface 19 partially protruding beyond the individual plugs, at which operating surface 19 the elastic operational control 14 can be moved in direction of the front 18 of the individual plugs 10, 11, 12. Lateral guiding elements 9 are allocated to each elastic operational control 14 with the operating surfaces 19. The guiding elements 9 cover the elastic operational controls 14, 14.1, 14.2 at the left and right sides and protect them from breaking. The operating surfaces 19 are supported by the guide elements 9 shown in FIG. 1 and are defined in their end positions by means of stops 8.

At the elastic operational controls 14 in the region in which the individual plugs are located in the plug housing 15 locking elements 20, are embodied e.g. as “locating lugs”, which when inserting each individual plug 10, 11, 12 into the plug housing 15 engage with correspondingly profiled recesses 23 at the back 21 of each individual plug or recesses 24 of the plug housing 15 and thus form a compact multipolar plug group.

FIGS. 1, 2 and 2a clarify in the synopsis the concept according to the invention, according to which the individual plugs 10, 11, 12 combined to the modular plug group 4 are interconnected and that via the first connection unit composed of a locking element 20.1 at the individual plug 11 with engagement into the recess 23 at the individual plug 10. The first individual plug of a modular plug group, for instance No. 10 engages with its locking element 20 into a corresponding recess 24 at the plug housing 15.

Due to the elastic operational controls 14, also to be understood as front rockers, via the operating surfaces 19 the engagement between the locating lugs 20 and the recesses 23, 24 can also be released and the individual plugs can be removed again.

Moreover, the example of embodiment drafted in FIG. 1 uses the stops 8 of the guiding elements 9 to define the insertion and removal sequence of the individual plugs by the stops 8 engaging into the recesses 7 of the respective preceding plug, i.e. for instance stop 8.11 into recess 7.10.

This results in an insertion sequence of the individual plugs 10, then 11, then 12. Removal can be performed either as a modular plug group 4 composed of the individual plugs 10, 11, 12 completely in one piece, by opening at the operational control 14.10 the front connection unit towards the plug housing 15 or by removing successively the individual plugs in reverse sequence, i.e. starting the individual plugs 12.

As FIGS. 5 to 7 show, according to a further advantageous embodiment of the plug-in connector the individual plugs 10, 11, 12 comprise additional elastic elements lateral to the front operational controls 14, such as rockers 40, 41 or 42, 43, which are arranged at the back of each individual plug such that they engage laterally, i.e. at right angle to the plugs arranged in a row from each individual plug outwards into the lateral wall 45 of the plug housing 15. Between the right rocker, e.g. 40 and the left rocker, e.g. 41 at the back of the first plug 1 preferably a clearance remains for the middle elastic operational control 14.2 with the guiding elements 9.2 of the subsequent individual plug, e.g.,. The rockers 40 to 43 comprise locking elements 44, to which appropriate recesses 46 are allocated in the plug housing. It goes without saying that other forms of embodiments of the locking elements are also possible.

When inserting the second individual plug 2 (cp. FIGS. 5 to 7) the lateral “rockers” e.g. 40, 41 of the “first” individual plug e.g. 1 are blocked by means of the guiding elements 9.2 of the “second” individual plug 2. When releasing the middle locking mechanism 14.1 or the engagement of the individual plug 1, the two lateral locking mechanisms 40, 41 are still blocked in the plug housing 15. Therefore, unlocking of the multipolar plug group can be performed only in defined sequence. The individual plug inserted last, for instance in FIG. 5 the individual plug 2, can be released from the preceding individual plug 1 by actuating the operating element 19 towards the front 18, what causes the locking element 20.2 to be withdrawn from the recess 23.1 at the plug 1. The two lateral rockers 42, 43 with their locking elements 44 can be withdrawn from the walls 45 of the plug housing 15, as they are not locked.

Supplementary a locking wedge 47 could be inserted between the last individual plug, e.g. 2 in FIG. 6 and the plug housing 15 and in this way also its lateral rockers 43, 44 could be locked. Preferably, at such a locking wedge 47 an operating surface is provided for removal.

The individual plugs in the drawings can be removed from the plug housing, what results in a good recyclability of the individual plugs. The individual plugs engaged in row in this way do not require any intermediate walls in the plug housing 15, resulting in a compact construction while maintaining a scalable plug. FIG. 4 shows here a door control device 30 for an automobile, in which the plug housing 15 is inserted into the control housing without intermediate walls for the individual plugs 10, 11, 12.

FIG. 3 shows a door control device for an automobile, wherein individual plugs, e.g. four individual plugs 31, 32, 33, 34, engaged to a multipolar plug group, are inserted in row into the plug housing 15 without any intermediate walls. Here, during insertion locking is automatically performed due to the friction-locked engagement of the locking elements 20.X effected via the elastic element 14.X. As is shown in FIG. 3, the modular construction of a plug of individual plugs 32 to 34 can be performed with identical dimensions or as is shown with individual plug 31 with different dimensions.

In FIG. 7 also the electrical components of the plug-in connector have been sketchily supplemented. Thus, in this example of embodiment in the plugs metallic sleeves 123 are molded into openings 124, which sleeves act as sockets for corresponding pins 101, 102, said pins 101, 102 being fixed in corresponding openings 153 on a printed circuit board 100 located in the interior of the housing and being electrically connected to tracks. The metallic sleeves 123 of the plugs are connected to connecting cables 125. As a matter of course, in this case the electrical connections are only exemplified and can be optionally varied, in particular allocation of sleeves and pins to plug or housing can be exchanged

1-14. (canceled)

15. A plug-in connector comprising:
at least one plug having one or more contacts;
a housing including at least one socket having one or more connection contacts, wherein the one or more contacts of the plug (123) being brought into contact with the connection contacts (101, 102) of the socket; and
a modular plug group (3, 4) assembled from two or more individual plugs (1, 2, 10, 11, 12, 31-34); wherein the socket is configured so that the individual plugs in the modular plug group that are inserted into the plug housing (15) form a plug group comprising at least two individual plugs (1, 2, 10, 11, 12, 31-34) arranged in a row.

16. The plug-in connector according to claim 15, wherein between at least two individual plugs (1-2, 10-11, 11-12) a connection unit is provided, which connects the front (18) of the one individual plug (2, 12) to the back (21) of the other individual plug (1, 11).

17. The plug-in connector according to claim 16, wherein the connection unit comprises a locking mechanism, which when inserting the individual plugs (1, 2, 10, 11, 12, 31-34) into the plug housing (15) each engage with a detent (20) into the back of the respective other individual plug or the plug housing (15).

18. The plug-in connector according to claim 17, wherein the locking mechanism comprises an unlocking device, wherein the detent is connected to an operational control (14) that can be operated and wherein by means of the operational control (14) the detent can be removed from the back of the respective other individual plug or from the plug housing.

19. The plug-in connector according to claim 15, wherein at least one individual plug (1, 2, 10-12, 31-34) comprises two lateral connection units (40-43), which connect the individual plug (1, 2, 10-12, 31-34) to the plug housing (15).

20. The plug-in connector according to claim 19, wherein the individual plugs are provided so that the individual plugs can be inserted into the plug housing only in a defined sequence and can be removed only in reverse sequence or jointly as a plug group.

21. The plug-in connector according to claim 20, wherein at least one individual plug (1, FIG. 6) the lateral connection units (40, 41) and at a second individual plug a molding (9.2) is provided in such form that the lateral connection units (40, 41) are locked at the first individual plug (1) in the inserted state, so that the first individual plug (1) can be removed only after removal of the second individual plug (2).

22. The plug-in connector according to claim 15, wherein each individual plug (1, 2, 10-12, 31-34) comprises a guiding and coding web (13), which engages with an accordingly profiled component (16) in the plug housing (15) and which guides assembly of the components when plugging individual plug (1, 2, 10-12, 31-34) and socket.

23. The plug-in connector according to claim 15, wherein each individual plug comprises:
at the front (18) of the plug (1, 2) a first connection unit (14) is provided with a locking and unlocking unit, which comprises an elastic operational control (14) that can be operated with a detent (20), wherein the operational control (14) is fixed at the individual plug at a bottom side (22) which faces the contacts (101, 102) and which can be moved at the top side (17) of the individual plug which is opposite to the contacts (101, 102) and can be connected to the back (21) of a further individual plug (1) or to the plug housing; and
at the back at least a second connection unit with a locking and unlocking unit is provided, which comprises a lateral elastic element (40-43) with a detent (44), which connects the individual plug to the lateral wall (45) of the plug housing (15).

24. The plug-in connector according to claim 15, wherein the plug housing (15) does not comprise any intermediate walls in the connection region of the individual plugs (10-12, 31-34) which can be assembled to a modular plug group.

25. The plug-in connector according to claim 24, wherein the plug housing comprises recesses (24) for the detents (20) of the operational control (14) of the first individual plug (1, 10) of the modular plug group arranged in row and recesses (46) for the detents (44) at the lateral connection units (41-43).

26. The plug-in connector according to claim 24, wherein the plug housing (15) sockets for guiding and coding webs (13) are provided, which cause assembly of the components when plugging individual plug (1, 2, 10-12, 31-34) and socket, wherein only in one position exactly one individual plug only and that only in exactly one direction towards the plug housing can be inserted.

27. A multipolar plug group for connecting conduits to a consumer, preferably to an electronic regulator or an electronic controller of an automobile, characterized in that the plug group (3, 4) of modular individual plugs (10-12, 31-34) is composed in such a way that at least two individual plugs (1, 2, 10-12, 31-34) arranged in a row form a plug group.

28. A door control device for an automobile having a plug-in connector with a plug and a socket, the device comprising:
at least one plug having one or more contacts;
a housing including at least one socket having one or more connection contacts, wherein the one or more contacts of the plug (123) being brought into contact with the connection contacts (101, 102) of the socket; and
a modular plug group (3, 4) assembled from two or more individual plugs (1, 2, 10, 11, 12, 31-34); wherein the socket is configured so that the individual plugs in the modular plug group that are inserted into the plug housing (15) form a plug group comprising at least two individual plugs (1, 2, 10, 11, 12, 31-34) arranged in a row.
